(19) United States
(12) Patent Application Publication
(10) Pub. No.: US 2010/0012031 A1
(43) Pub. Date: Jan. 21, 2010

(54) Method and apparatus for optically characterizing the doping of a substrate

(76) Inventors: Frank Torregrosa, Simiane (FR); Laurent Roux, Marseille (FR)

Correspondence Address: HORST M. KASPER, 13 FOREST DRIVE, WARREN, NJ, 07059, US

(21) Appl. No.: 12/308,446

(22) PCT Filed: Jun. 14, 2007
(86) PCT No.: PCT/FR2007/000992

§ 371 Date: Jan. 28, 2009

(30) Foreign Application Priority Data
Jun. 14, 2006 (FR) 0605329

(51) Int. Cl. C23C 14/48; G01N 21/55; G01N 21/95

(52) U.S. Cl. 118/712; 356/448

(57) ABSTRACT

The invention relates to a method of optical characterization, comprising a step of evaluating the doping of a substrate (SUB) using a reflected beam emanating from a light source, said method being carried out using apparatus comprising: said light source (LAS) to produce an incident beam (I) in an axis of incidence; a first detector (DET1, DET2) to measure the power of said reflected beam (R) in an axis of reflection; said axes of incidence and reflection crossing at a measurement point and forming a non-zero angle of measurement; and a polarizer (POL) disposed in the path of the incident beam (I). Furthermore, the light source (LAS) is monochromatic. The invention also envisages an ion implanter provided with said apparatus.

The present invention relates to a method and apparatus for optically characterizing the doping of a substrate.

In microelectronics, a routine operation consists in doping certain zones of a substrate, for e.g. a silicon, with an active species. The problem lies in controlling the concentration of the active species in the doped zone.

Doping is currently carried out using an ion implanter. In that technique, implantation of a substrate consists in bombarding it with ions that are accelerated by means of an intense electric field. Clearly, characterizing the doping during implantation cannot be carried out completely by electrical measurement since such measurement will be perturbed by the presence of neutral dopants, the effect of saturation due to sputtering, and the presence of secondary electrons.

A number of solutions have been proposed to estimate the concentration of dopant.

A first solution consists in measuring the sheet resistance of the zone using the method known to the skilled person as the four tips method. If doping has been carried out by ion implantation, such measurement is possible only after annealing the substrate. Further, that solution is inapplicable when the layer is very thin; tip probes that go through the layer no longer measure the resistance of the doped zone, but that of the substrate.

A second solution disclosed in document US-2005/0 140 976 consists in studying the propagation of an optically generated thermal wave in the doped zone. In practice, that solution cannot be used when the zone is very thin, because of extremely limited sensitivity.

A third solution uses ellipsometry; while it has certain advantages over the preceding solutions, it is very complex to implement.

A fourth solution can determine doping by making use of the fact that the refractive index of a sample, in other words its coefficient of reflection, is a function of its concentration of dopant. Thus, document US-2002/0 080 356 proposes illuminating a sample with polychromatic light using a beam at normal incidence and measuring the reflected beam. The measurement is not carried out on the substrate but on a sample coated with a resin of index that varies greatly as a function of the starting concentration. It is thus an indirect method, and it suffers from all of the limitations inherent to that type of method.

Above-mentioned document US-2005/0 140 976 combines a thermal type method with a polychromatic light reflectometry measurement. However, while the refractive index does indeed depend on the concentration of dopant, it also depends on the wavelength. This means that the accuracy of the measurement is affected thereby.

Moreover, document U.S. Pat. No. 6,417,515 proposes illuminating the substrate with monochromatic light and carrying out a differential measurement of the reflectivity using a detector receiving a portion of the incident beam and a detector receiving the reflected beam. Thus, variations in the refractive index are obtained as a function of wavelength. However, since the doped zone is not optically isotropic, there results relative uncertainty in the estimate of the refractive index.

Furthermore, document U.S. Pat. No. 6,727,108 describes a characterization method using apparatus that is relatively complex and consequently that is fairly expensive. In addition to a light source used to measure the concentration of the dopant, that apparatus includes an additional intermittent excitation source that is the source of the known limitations of that technique, comprising at least an unwanted anneal of the measurement zone. Further, the light source is a xenon lamp that thus suffers from the limitations inherent to polychromatic sources.

The present invention thus aims to provide a method of optically characterizing the doping of a substrate that is substantially improved both as regards accuracy and as regards sensitivity, using a substantially simplified apparatus.

In accordance with the invention, a method of optical characterization comprising a step of evaluating the doping of a substrate (SUB) using a reflected beam emanating from a light source is carried out using apparatus comprising:
said light source to produce an incident beam in an axis of incidence;
a first detector to measure the power of said reflected beam in an axis of reflection;
said axes of incidence and reflection crossing at a measurement point and forming a non-zero angle of measurement; and
a polarizer disposed in the path of the incident beam;

furthermore, the light source is monochromatic.

The polarizer enables the reflectivity measurement to be carried out on an identified optical axis of the substrate.

Preferably, said polarizer is arranged such that the incident beam is in transverse-magnetic mode in the plane of incidence defined by the incident and reflected beams.

In this configuration, the sensitivity of the measurement apparatus is optimized.

Further, the apparatus includes a differential amplifier receiving at its inputs a detection signal originating from the detector and a reference signal to produce a measurement signal.

Advantageously, the reference signal originates from a reference supply delivering a predetermined voltage.

In fact, when the light source is sufficiently stable, there is no need to resort to a differential measurement technique between the reflected beam and the incident beam.

Alternatively, when the apparatus includes a second detector to measure the power of the incident beam, the reference signal originates from said second detector.

In accordance with an additional characteristic of the invention, when the apparatus is adapted to a silicon substrate provided to present a nominal doping, the wavelength of the light source corresponds to a relative maximum of the difference in reflectivity between the non-doped substrate and the substrate presenting the nominal doping.

By way of example, the wavelength is included in one of the ranges included in the group comprising: the range 400-450 nanometers; the range 300-350 nanometers; and the range 225-280 nanometers.

Furthermore, since the angle of incidence is equal to half the measurement angle, this angle of incidence is equal to the Brewster incidence to within plus or minus 5 degrees.

Here again, the sensitivity of the apparatus is maximized.

The invention also envisages an ion implanter including optical characterization apparatus as specified above.

Further details of the present invention become apparent from the following description of embodiments that are given by way of illustration and with reference to the accompanying figures in which:

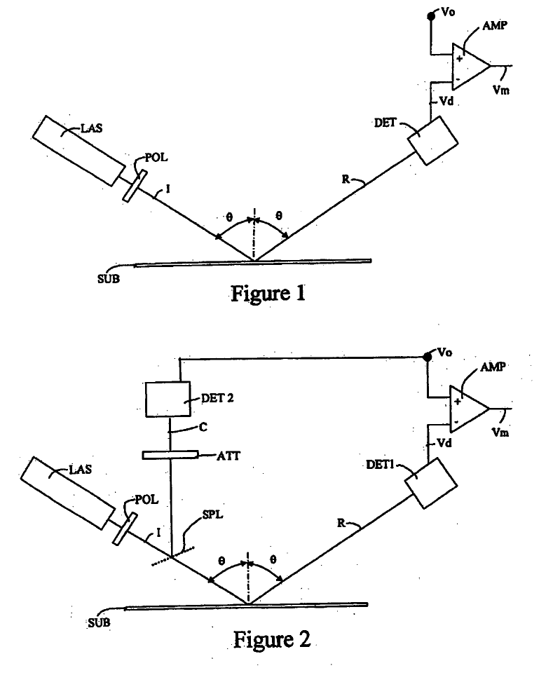

FIG. 1 is a skeleton diagram of a first embodiment of an optical characterization apparatus; and

FIG. 2 is a skeleton diagram of a second embodiment of an optical characterization apparatus.

Elements shown in both of the two figures are given the same references in each of them.

Referring to FIG. 1, in a first embodiment, an apparatus provided for optically characterizing a substrate SUB comprises a monochromatic light source LAS followed by a polarizer POL from which an incident beam I emanates that illuminates said substrate at an angle of incidence of θ.

This incident beam I reaches the substrate SUB at a measurement point to produce a reflected beam R. The measurement angle formed by the incident beam I and the reflected beam R is equal to twice the angle of incidence θ, it being understood that the bisector of this measurement angle is perpendicular to the plane of the substrate SUB.

A detector DET is disposed on the path of the reflected beam R to measure its power, producing a detection signal V_{d}.

One of the inputs of a differential amplifier AMP receives said detection signal V_{d} and another input receives a reference signal V₀ to produce a measurement signal Vₘ at its output. The origin of this reference signal is explained below.

The polarizer POL enables the substrate to be sensibilized along an identified optical axis. However, it is preferable to orientate said polarizer such that the incident beam I is in transverse-magnetic mode in the plane of incidence defined by the incident beam I and reflected beam R. In this mode, at the incidence termed the “Brewster” incidence, reflection of the incident beam I is minimized. This particular angle of incidence is defined by the following expression, in which n₁ and n₂ respectively represent the refractive index of the transmission medium for the incident beam I and that of the substrate, and in which Re signifies the real portion:

tan θ=Re(n₂)/Re(n₁)

It should be noted at this juncture that the index of the substrate n₂ varies with its degree of doping, and so the Brewster incidence is not the same for a doped substrate and for a non-doped substrate.

Thus, by adopting an angle of incidence close to the Brewster incidence, the power of the reflected beam R is very low but, in contrast, the variations in the reflection coefficient of the substrate SUB as a function of the refractive index are maximized.

It is thus desirable to fix the value of the angle of incidence in a range centered on the value of the Brewster incidence either for a non-doped substrate or for a substrate with the maximum doping that is to be characterized. For non-doped silicon at the wavelength of 405 nanometers, the Brewster incidence is 79.5 degrees. The recommended range then extends from 74 to 84 degrees, giving a tolerance of 5 degrees either side of the central value.

It should also be noted that for a given angle of Incidence, the reflectivity of a doped substrate relative to that of the non-doped substrate as a function of the wavelength of the light source has a pseudo-periodic appearance having a succession of relative maxima.

It is thus preferable to select a source that corresponds to one of these maxima, and preferably the highest of them.

Further, the optimum wavelength is also a function of the depth at which the dopant concentration is measured: the shallower the depth, the shorter will be the wavelength. Three preferred ranges have been discovered; the first is from 400 to 450 nanometers, the second is from 300 to 350 nanometers and the third is from 225 to 280 nanometers.

Certain lasers are now very stable over time. This means that the power of the incident beam I varies very little. Under such circumstances, the reference signal V₀ supplied to the amplifier AMP is a reference voltage that originates from a stabilized supply (not shown in the figure); This reference voltage V₀ advantageously takes the value of the detection signal V_{d} obtained following illumination of a non-doped substrate.

However, it may be necessary to accommodate possible variations in the power of the light source.

Thus, and referring now to FIG. 2, in a second embodiment, the optical characterization apparatus still comprises a monochromatic light source LAS followed by a polarizer POL from which an incident beam I emanates what illuminates said substrate at an angle of incidence θ.

As before, a first detector DET1 is disposed on the path of the reflected beam R in order to restitute the power, producing the detection signal V_{d}.

Similarly, one of the inputs of the differential amplifier AMP receives said detection signal V_{d} and another input receives a reference signal V₀ to produce a measurement signal Vₘ at its output.

Under such circumstances, the origin of the reference signal is different.

An optical separator SPL is interposed in the path of the incident beam I between the polarizer POL and the substrate SUB to deflect a portion of said beam towards a second detector DET2. Further, an attenuator ATT is disposed between said separator SPL and the second detector DET2 that now produces the reference signal V₀.

The attenuator ATT has an attenuation coefficient such that the reference signal V₀ substantially corresponds to the detection signal V_{d} obtained following illumination of a non-doped substrate. In this manner, the two detectors DET1, DET2 analyze light beams with similar characteristics.

However, replacement of the optical attenuator ATT with an electronic attenuator arranged downstream from the second detector may also be envisaged.

The apparatus described above may be used to characterize a doped substrate, in particular to produce a map of said substrate.

It may also be installed in situ, in an ion implanter, to monitor doping during implantation. Further details of the implanter are not provided since they form part of the knowledge of the skilled person.

The examples of the invention presented above were selected because of to their concrete nature. It would not be possible to provide an exhaustive list of all of the embodiments that are encompassed within this invention. In particular, any means described above may be replaced by equivalent means without departing from the ambit of the present invention.

1. A method of optical characterization, comprising a step of evaluating the doping of a substrate (SUB) using a reflected beam emanating from a light source, said method being carried out using apparatus comprising:
said light source (LAS) to produce an incident beam (I) in an axis of incidence;
a first detector (BET1, BET2) to measure the power of said reflected beam (R) in an axis of reflection; said axes of incidence and reflection crossing at a measurement point and forming a non-zero angle of measurement (26); and
a polarizer (POL) disposed in the path of the incident beam (I); characterized in that said light source (LAS) is monochromatic.

2. A method according to claim 1, characterized in that said polarizer (POL) is arranged such that the incident beam (I) is in transverse-magnetic mode in the plane of incidence defined by the incident (I) and reflected (R) beams.

3. A method according to claim 1, characterized in that said apparatus includes a differential amplifier (AMP) receiving at its inputs a detection signal (V_{d}) originating from said detector (DET1, DET2) and a reference signal (Vo) to produce a measurement signal (Vₐ).

4. A method according to claim 3, characterized in that said reference signal (Vo) originates from a reference supply delivering a predetermined voltage.

5. A method according to claim 3, characterized in that when said apparatus includes a second detector (DET2) to measure the power of said incident beam (I), said reference signal {Vₒ) originates from said second detector (DET2).

6. A method according to claim 1, characterized in that when the apparatus is adapted to a silicon substrate (SUB) provided to present a nominal doping, the wavelength of said light source (LAS) corresponds to a relative maximum of the difference in reflectivity between the non-doped substrate and the 10 substrate having said nominal doping.

7. A method according to claim 6, characterized in that said the wavelength is included in one of the ranges included in the group comprising: the range 400-450 nanometers; the range 300-350 nanometers; and the range 225-280 nanometers.

8. A method according to claim 1, characterized in that since the angle of incidence (8) is 20 equal to half of said measurement angle, said angle of incidence is equal to the Brewster incidence to within plus or minus 5 degrees.

9. An ion implanter, characterized in that it includes apparatus in accordance with claim 1.
